(19) United States
(12) Patent Application Publication
(10) Pub. No.: US 2012/0273901 A1
(43) Pub. Date: Nov. 1, 2012

(54) SEMICONDUCTOR DEVICE AND METHOD FOR MANUFACTURING THE SAME

(75) Inventors: Haizhou Yin, Poughkeepsie, NY (US); Huicai Zhong, Beijing (CN); Huilong Zhu, Poughkeepsie, NY (US); Zhijiong Luo, Poughkeepsie, NY (US)

(73) Assignee: INSTITUTE OF MICROELECTRONICS, CHINESE ACADEMY OF SCIENCE, BEIJING (CN)

(21) Appl. No.: 13/063,733

(22) PCT Filed: Sep. 27, 2010
(86) PCT No.: PCT/CN10/77316

§ 371 Date: Mar. 11, 2011

(51) Int. Cl. H01L 29/78; H01L 21/336

(52) U.S. Cl. 257/410; 438/299; 257/E21.409; 257/E29.255

(57) ABSTRACT

The present invention relates to a semiconductor device and a method for manufacturing the same. According to the present invention, when a gate is formed via a replacement gate process, a portion of a work function metal layer and a portion of a first metal layer are removed after the work function metal layer and the first metal layer are formed, and then the removed portions are replaced with a second metal layer. A device having such a gate structure greatly reduces the resistivity of the whole gate, due to a portion of the work function metal layer with a high resistivity being removed and the removed portion being filled with the second metal layer with a low resistivity, thereby AC performances of the device are improved.

### FIELD OF THE INVENTION

The present invention generally relates to a semiconductor device and a method for manufacturing the same, and particularly, to a method for manufacturing a low resistance gate device based on a replacement gate process.

### BACKGROUND OF THE INVENTION

With the development of the semiconductor technology, better properties and more powerful functions of an integrated circuit (IC) require a larger element density, and accordingly, spaces between elements as well as sizes of the elements shall be further reduced. Nowadays, the application of the 32/22 nanometer IC technology has become an inevitable trend of the IC development and a topic competitively developed by major international semiconductor companies and research institutes. Further, the gate engineering for CMOS device, the core of which is the ‘high-k dielectric/metal gate’ technique, has been a most representative key technology in the 32/22 nanometer technology, and related materials, processes, and structures have been studied extensively.

Currently, research on the high-k gate dielectric/metal gate technology can be generally divided into two areas, i.e., the gate-first process and the replacement gate process (also called as the gate-last process). A typical replacement gate process includes steps of forming a dummy gate, forming spacers for the dummy gate and source/drain regions, removing the dummy gate to form an opening, and then filling metals having different work functions into the opening to form a gate. This process has an advantage that the gate is formed after forming the source and the drain, so that the gate does not need to bear a high anneal temperature. This avoids any possible transfer of the work function due to a high thermal budget. However, in this process, some work function metal, which has a relatively high resistivity, is formed on sidewalls of the opening, causing the gate resistivity to be very high, and a too high gate resistivity will affect the Alternating Current (AC) performance of the device.

Therefore, it is necessary to provide a device structure based on replacement gate process and a method for manufacturing the same, which are capable of reducing the gate resistivity of the device.

### SUMMARY OF THE INVENTION

In order to solve the above problem, the present invention provides A method for manufacturing a semiconductor device, comprising: providing a semiconductor substrate; forming a dummy gate stack and spacers on the lateral surfaces of the dummy gate stack on the semiconductor substrate, and forming a source region and a drain region in the semiconductor substrate on either side of the dummy gate stack, wherein the dummy gate stack comprises a high-k gate dielectric layer and a dummy gate; removing the dummy gate to expose the high-k gate dielectric layer, so as to form an opening; forming a work function metal layer to cover the bottom and sidewalls of the opening, and forming a first metal layer to fill up the opening on the work function metal layer; removing an upper portion of the work function metal layer and an upper portion of the first metal layer in the opening; and filling up the opening with a second metal layer.

The first and second metal layers may be formed of one or more materials selected from a group comprising Al, Ti, Ta, W, and Cu. In this process, after the dummy gate is removed, the high-k gate dielectric layer therebelow may be further removed and a new high-k gate dielectric layer may be redeposited. This has an advantage of avoiding damage to the high-k gate dielectric layer when the dummy gate is removed.

The present invention further provides a semiconductor device, comprising: a semiconductor substrate; a gate stack and its spacers formed on the semiconductor substrate; and a source region and a drain region formed in the semiconductor substrate on either side of the gate stack; wherein the lower portion of the gate stack comprises: a high-k gate dielectric layer, a work function metal layer formed on the high-k gate dielectric layer, and a first metal layer formed on the work function metal layer, wherein the bottom and sidewalls of the first metal layer are in contact with the work function metal layer; and wherein an upper portion of the gate stack is a second metal layer formed on the first metal layer and the work function metal layer. The first and second metal layers may be formed of one or more materials selected from a group comprising Al, Ti, Ta, W, and Cu. In the above semiconductor device and the method for manufacturing the same, a resistivity of the second metal layer is smaller than that of the first metal layer; and a resistivity of the first metal layer is smaller than that of the work function metal layer.

According to a method of the present invention, a part of the work function metal layer and the first metal layer are removed after they are formed, and the removed portions are replaced by a second metal layer with a low resistivity. This greatly decreases the gate resistivity and thus effectively improves the AC performance of the device.

### BRIEF DESCRIPTION OF THE DRAWINGS

FIG. 1 illustrates a flowchart of a method for manufacturing a semiconductor device according to an embodiment of the present invention; and

FIGS. 2-11 illustrate schematic diagrams of respective phases of the semiconductor device manufacturing process according to the embodiment of the present invention.

### DETAILED DESCRIPTION OF THE EMBODIMENTS

The present invention generally relates to a method for manufacturing a semiconductor device. The following disclosure provides several different embodiments or examples to implement different structures according to the present invention. In order to simplify the description of the present invention, components and arrangements of some specific examples are described in the following text. Of course, they are just illustrative, and do not intend to limit the present invention. In addition, reference numbers and/or letters can be repeatedly used in different examples of the present invention for the purposes of simplification and clearness, without indicating the relationships between the discussed embodiments and/or arrangements. Further, the present invention provides examples of various specific processes and materials, but a person skilled in the art can realize the availability of other processes and/or usage of other materials. Moreover, a structure described as follows in which a first feature is “on” a second feature, may include an embodiment where the first and second features are formed to directly contact with each other, or an embodiment where another feature is formed between the first and second features so that the first and second features may not directly contact with each other.

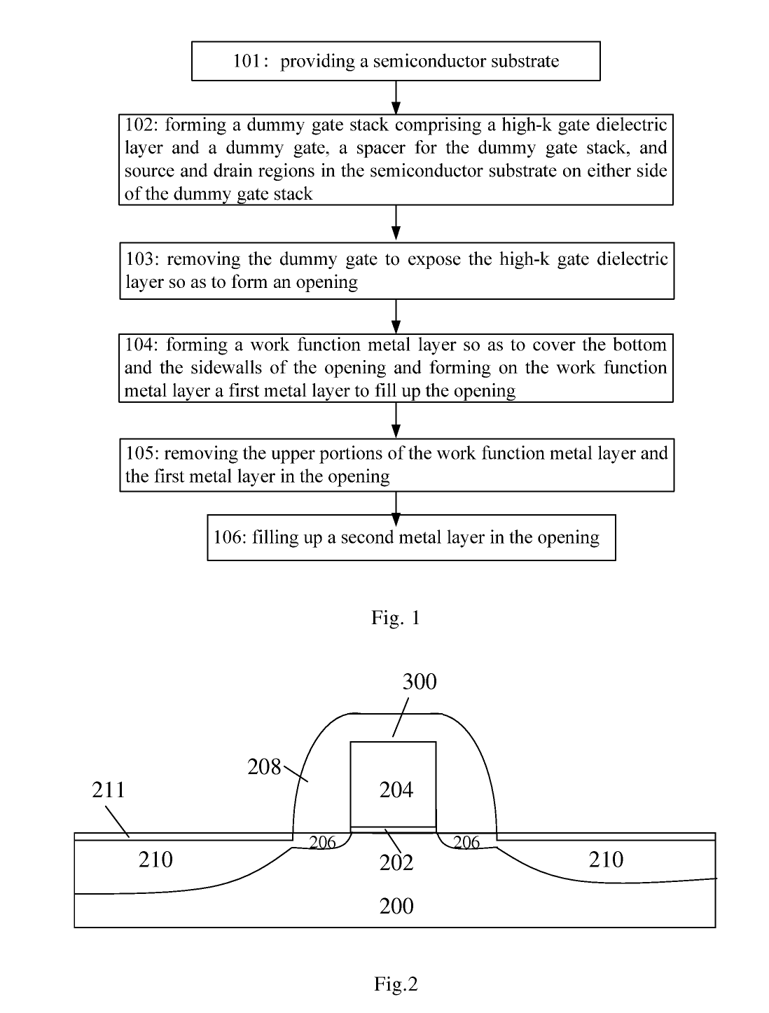

Referring to FIG. 1, FIG. 1 illustrates a flowchart of a method for manufacturing a semiconductor device according to an embodiment of the present invention. In step 101, a semiconductor substrate 200 is provided, as illustrated in FIG. 2. In one embodiment, the substrate 200 includes a silicon substrate (e.g., wafer) in a crystal structure. According to known design requirements (e.g., a p-type substrate or a n-type substrate) in the prior art, the substrate 200 may include various doping configurations. In other examples, the substrate 200 may also include other semiconductors, such as germanium and diamond, or a compound semiconductor, such as SiC, GaAs, InAs, or InP. In addition, the substrate 200 may optionally include an epitaxial layer, which may be manipulated by stress for performance enhancement, and may include a silicon-on-insulator (SOI) structure.

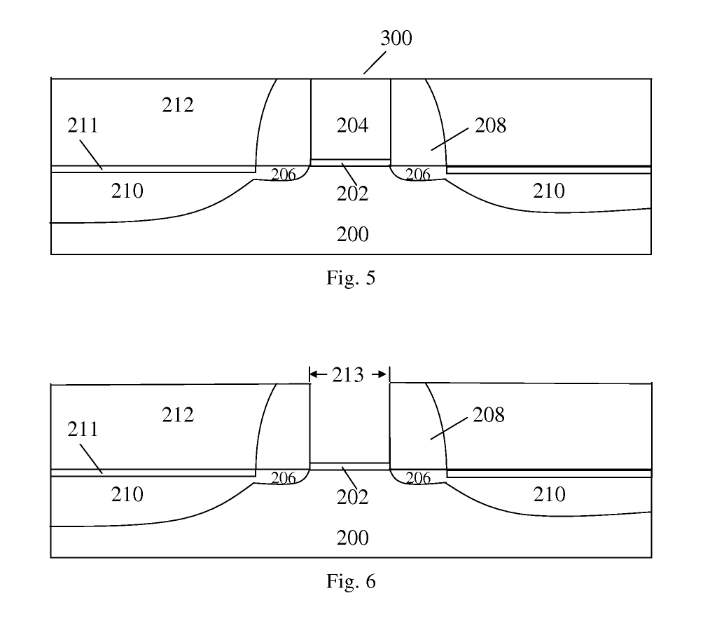

In step 102, a dummy gate stack 300 and a spacer 208 are formed on the substrate; and source and drain regions 210 are formed in the semiconductor substrate 200 on either side of the dummy gate stack 300. The dummy gate stack 300 includes a high-k gate dielectric layer 202 and a dummy gate 204, as illustrated in FIG. 5. The device structure as illustrated in FIG. 5 is an intermediate structure for forming a device structure of the present invention, and the intermediate structure can be formed through conventional processing steps, materials and equipments, which will be understood by a person skilled in the art.

Specifically, the high-k gate dielectric layer 202 and the dummy gate 204 are firstly formed on the semiconductor substrate 200, as illustrated in FIG. 2. The high-k gate dielectric layer 202 may comprise a high k dielectric material (e.g., a material having a higher dielectric constant as compared with silicon oxide). Examples of the high-k dielectric material include hafnium-based material, such as HfO₂, HfSiO, HfSiON, HfTaO, HfTiO, or HfZrO, or any combination thereof, and/or other appropriate materials. The dummy gate 204, for example, may be made of polysilicon. In this embodiment, the material of the dummy gate 204 includes amorphous silicon. The gate dielectric layer 202 and the dummy gate 204 may be formed through an MOS process, such as deposition, photolithography, etching and/or other appropriate methods. In the following descriptions, the high-k gate dielectric layer 202 and the dummy gate 204 are referred to as the dummy gate stack 300.

Next, the spacers 208 are formed to cover the dummy gate stack 300, as illustrated in FIG. 2. The spacers 208 may be formed of SiN, SiO₂, SiON, SiC, silica glass doped with fluoride, or low-k dielectric material, or any combination thereof, and/or other appropriate materials. The spacers 208 may be of a multi-layer structure. In this embodiment, the spacers 208 are formed of SiN. The spacers 208 may be formed through a method including depositing appropriate dielectric materials. One segment of the spacers 208 covers the dummy gate stack 300, and such a structure can be obtained by using a process known by a person skilled in the art. In other embodiments, the spacers 208 may not cover the dummy gate stack 300.

Next, as illustrated in FIG. 2, the source and drain regions 210 are formed. The source and drain regions 210 may be formed by implanting p-type dopants, n-type dopants or impurity into the substrate 200 according to the required transistor structure. The source and drain regions 210 may be formed by a method including photolithography, ion implantation, diffusion and/or other appropriate process, after which, the source and drain regions 210 are annealed to activate the dopants. Specifically, source/drain (S/D) shallow junction regions 206, generally including S/D extension regions and/or halo regions, may also be formed before forming the source and drain regions 210.

In particular, after forming the source and drain regions 210, metal silicide layers 211 may be formed on the semiconductor substrate 200 within the source and drain regions 210. The metal silicide layers 211 may be formed via a self alignment process. Firstly, a metal material such as Co, Ni, Mo, Pt or W is deposited on the device. Then, an annealing is carried out, so that the metal reacts with the surface of the silicon substrate where the source and drain regions 210 are located to form metal silicides. Next, the non-reacted metal is removed to form the self-aligned metal silicide layers 211, and thus, a structure as illustrated in FIG. 2 is formed.

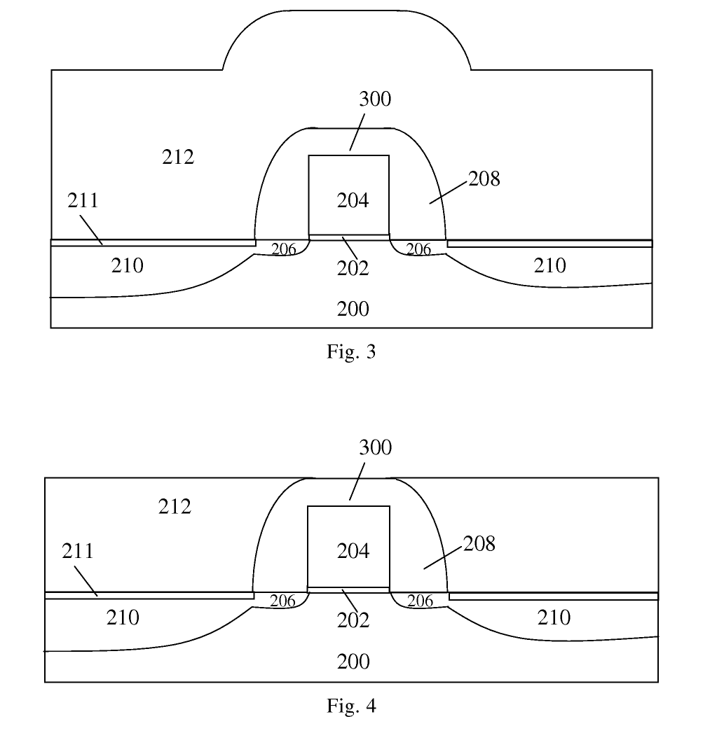

Next, an interlayer dielectric (ILD) layer 212 is deposited on the device, as illustrated in FIG. 3. The ILD layer 212 may be made of, but not limited to, undoped silicon oxide (SiO₂), doped silicon oxide (e.g., borosilicate glass, boron-phosphorosilicate glass, etc) or silicon nitride (Si₃N₄). The ILD layer 212 may be formed by, for example, chemical vapor deposition (CVD), physical vapor deposition (PVD), atomic layer deposition (ALD) and/or other appropriate processes. The ILD layer 212 may be of a multi-layer structure.

Next, the ILD layer 212 and the spacers 208 are planarized to expose an upper surface of the dummy gate 204. For example, the ILD layer 212 may be removed by a chemical mechanical polishing (CMP) method, the upper surface of the SiN spacer 208 serving as a stop layer and firstly exposed, as illustrated in FIG. 4. Next, a CMP or a reactive ion etching is carried out on the spacers 208 to remove an upper portion thereof so as to expose the dummy gate 204, as illustrated in FIG. 5.

Next, in step 103, the dummy gate 204 is removed to expose the high-k gate dielectric layer 202, so as to form an opening 213, as illustrated in FIG. 6. For example, step 103 can be performed by selectively etching the dummy gate 204 and stopping on the high-k gate dielectric layer 202, so as to form the opening 213. The dummy gate 204 may be removed through a wet etching and/or a dry etching. In one embodiment, the wet etching process includes TMAH, KOH or other appropriate etchant solution. In other embodiments of the present invention, the high-k gate dielectric layer may be further removed and a new high-k gate dielectric layer is deposited, for the purpose of ensuring a surface quality of the gate dielectric layer. There is no limitation for the employment of this method in the present invention.

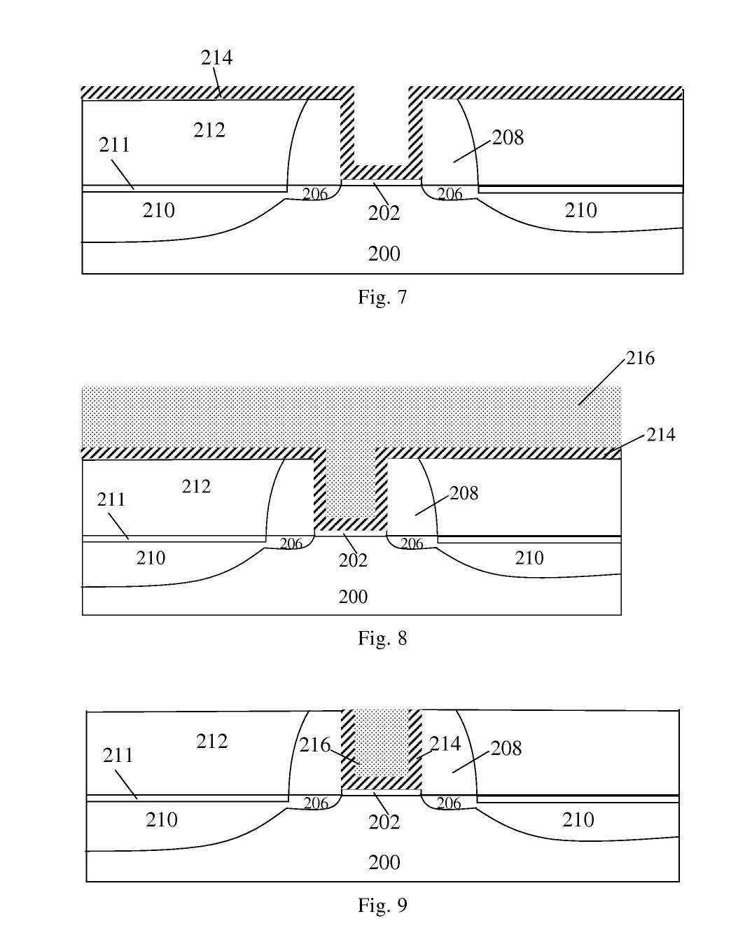

In step 104, a work function metal layer 214 is formed to cover the bottom and the sidewalls of the opening 213, and a first metal layer 216 is formed on the work function metal layer 214 to fill up the opening, as illustrated in FIG. 9. Specifically, the work function metal layer 214 is firstly formed within the opening 213, as illustrated in FIG. 7. The material of the work function metal layer 214 may include TiN, TiAlN, TaN, or TaAlN, or any combination thereof. Next, the first metal layer 216 is formed on the work function metal layer 214, as illustrated in FIG. 8. The material of the first metal layer 216 may be a metal with a resistivity lower than that of the work function metal layer 214, such as Al, Ti, Ta, W, Cu, etc. The work function metal layer 214 and the first metal layer 216 may be formed by deposition, which can be carried out through sputtering, PLD, MOCVD, ALD, PEALD or other appropriate methods. Next, the work function metal layer 214 and the first metal layer 216 are planarized, so as to form the work function metal layer 214 on the bottom and the sidewalls of the opening 213, and the first metal layer 216 located on the work function metal layer 214 and filling up the opening 213, as illustrated in FIG. 9. The first metal layer 216 and the work function metal layer 214 on the ILD layer 212 and the spacers 208 can be removed through a CMP method by taking the oxide of the ILD layer 212 and SiN of the spacers 208 as a stop layer, so as to form the structure as illustrated in FIG. 9.

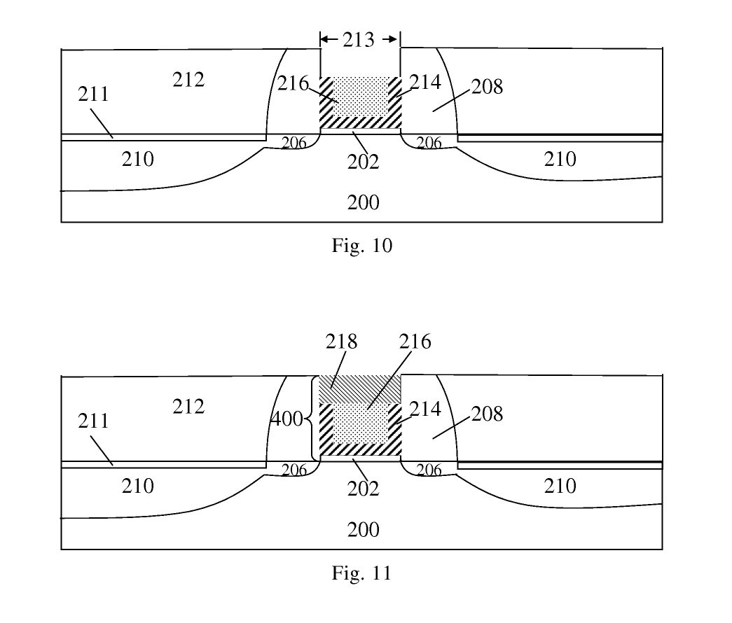

In step 105, upper portions of the work function metal layer 214 and the first metal layer 216 in the opening 213 are removed, as illustrated in FIG. 10. The work function metal layer 214 and the first metal layer 216 can be partially etched through a dry or wet etching technology, so as to form the structure as illustrated in FIG. 10.

In step 106, a second metal layer 218 is filled within the opening 213, thereby forming a gate stack 400 of the device, as illustrated in FIG. 11. The second metal layer 218 may be deposited on the device, and then the second metal layer 218 on the ILD layer 212 and the spacers 208 can be removed through a CMP method by taking the oxide of the ILD layer 212 and SiN of the spacers 208 as a stop layer, so as to form the second metal layer 218 and the gate stack 400 of the device. The material of the second metal layer 218 may be a metal with a resistivity lower than that of the work function metal layer 214, such as Al, Ti, Ta, W, Cu, etc. Preferably, the material of the second metal layer is Cu, or Al, or a combination thereof.

In steps 105 and 106, the work function metal layer 214 and the first metal layer 216 are partially removed, and the removed portions are replaced by the second metal layer 218. The residual work function metal layer 214 is still capable of adjusting the work function of the device. Since the resistivity of the second metal layer 218 is lower than that of the work function metal layer 214, the resistivity of the whole gate is reduced. The first metal layer 216 and the second metal layer 218 may be formed of the same or different metals. Preferably, the resistivity of the second metal layer 218 is lower than that of the work function metal layer 214, and the resistivity of the first metal layer 216 is lower than that of the work function metal layer 214. Preferably, the thickness of the second metal layer 218 is larger than that of the first metal layer 216. The aforementioned preferable embodiments aim for further reducing the gate resistance and improving the device performance.

During the process of manufacturing a CMOS transistor by using the replacement gate (or Gate last) technology, a portion of the work function metal layer 214 and a portion of the first metal layer 216 are removed after forming the work function metal layer 214 and the first metal layer 216, and the removed portions are replaced with a second metal layer 217 made of another low resistivity metal. In a device having such a structure, the resistivity of the whole gate is greatly reduced due to a portion of the work function metal layer having a high resistivity being removed and the removed portion being replaced with a metal having a low resistivity, thereby AC performance of the device is improved.

According to the above method, it is further provided a semiconductor device with a structure as illustrated in FIG. 11. The semiconductor device comprises a semiconductor substrate 200; a gate stack and spacers 208 formed on the semiconductor substrate 200; and source and drain regions 210 formed in the semiconductor substrate on either side of the gate stack, wherein a lower portion of the gate stack comprises a high-k gate dielectric layer 202, a work function metal layer 214 formed on the high-k gate dielectric layer 202, and a first metal layer 216 formed on the work function metal layer 214; the bottom and the sidewalls of the first metal layer 216 are in contact with the work function metal layer 214; and an upper portion of the gate stack comprises a second metal layer 218 formed on the first metal layer 216 and the work function metal layer 214.

Preferably, the resistivity of the second metal layer 218 is smaller than that of the first metal layer 216, and the resistivity of the first metal layer 216 is smaller than that of the work function metal layer 214.

The first metal layer 216 and the second metal layer 218 may be formed of one or more materials selected from a group consisting of Al, Ti, Ta, W, and Cu. Preferably, the metal layer is made of one or more materials selected from a group comprising Cu and Al.

The work function metal layer 214 may be formed of one or more materials selected from a group comprising TiN, TiAlN, TaN, and TaAlN.

Preferably, the thickness of the second metal layer is larger than that of the first metal layer.

Although the exemplary embodiments and the advantages have been detailedly described herein, it shall be appreciated that various changes, substitutions and modifications may be made to these embodiments without deviating from the spirit of the present invention and the protection scopes defined by the accompanied claims. With respect to other examples, it will be easily understood by a person skilled in the art that the sequence of the processing steps may be changed while maintaining the protection scope of the present invention.

Furthermore, the present invention can be applied without limiting to the processes, structures, manufacturing, compositions, means, methods, and steps of the specific embodiments described in the specification. According to the disclosure of the present invention, a person skilled in the art will easily appreciate that when the processes, structures, manufacturing, compositions, means, methods and steps currently existing or to be developed in future are adopted to perform functions substantially the same as corresponding embodiments described in the present invention, or achieve substantially the same effects, a person skilled in the art can apply them according to the present invention. Therefore, these processes, structures, manufacturing, compositions, means, methods, and steps fall within the scope of the accompanied claims of the present invention.

1. A method for manufacturing a semiconductor device, comprising:
A. providing a semiconductor substrate;
B. forming a dummy gate stack and spacers on the lateral surfaces of the dummy gate stack on the semiconductor substrate, and forming a source region and a drain region in the semiconductor substrate on either side of the dummy gate stack, wherein the dummy gate stack comprises a high-k gate dielectric layer and a dummy gate;
C. removing the dummy gate to expose the high-k gate dielectric layer, so as to form an opening;
D. forming a work function metal layer to cover the bottom and sidewalls of the opening, and forming a first metal layer to fill up the opening on the work function metal layer;
E. removing an upper portion of the work function metal layer and an upper portion of the first metal layer in the opening; and
F. filling up the opening with a second metal layer.

2. The method according to claim 1, wherein the first and second metal layers are formed of one or more materials selected from a group comprising Al, Ti, Ta, W, and Cu.

3. The method according to claim 1, wherein the work function metal layer is formed of one or more materials selected from a group comprising TiN, TiAlN, TaN, and TaAlN.

4. The method according to claim 1, wherein the thickness of the second metal layer is larger than that of the first metal layer.

5. The method according to claim 1, wherein the resistivity of the second metal layer is smaller than that of the first metal layer, and the resistivity of the first metal layer is smaller than that of the work function metal layer.

6. The method according to claim 5, wherein the second metal layer is made of one or more materials selected from a group comprising Cu and Al.

7. The method according to claim 1, after removing the dummy gate in step C, the method further comprising:
removing the high-k gate dielectric layer; and
redepositing the high-k gate dielectric layer in the opening.

8. A semiconductor device, comprising:
a semiconductor substrate;
a gate stack and its spacers formed on the semiconductor substrate; and
a source region and a drain region formed in the semiconductor substrate on either side of the gate stack;
wherein the lower portion of the gate stack comprises: a high-k gate dielectric layer, a work function metal layer formed on the high-k gate dielectric layer, and a first metal layer formed on the work function metal layer, wherein the bottom and sidewalls of the first metal layer are in contact with the work function metal layer; and
wherein an upper portion of the gate stack is a second metal layer formed on the first metal layer and the work function metal layer.

9. The semiconductor device according to claim 8, wherein the first and second metal layers are formed of one or more materials selected from a group comprising Al, Ti, Ta, W, and Cu.

10. The semiconductor device according to claim 8, wherein the work function metal layer is formed of one or more materials selected from a group comprising TiN, TiAlN, TaN, and TaAlN.

11. The semiconductor device according to claim 8, wherein the thickness of the second metal layer is larger than that of the first metal layer.

12. The semiconductor device according to claim 8, wherein the resistivity of the second metal layer is smaller than that of the first metal layer, and the resistivity of the first metal layer is smaller than that of the work function metal layer.

13. The semiconductor device according to claim 8, wherein the second metal layer is made of one or more materials selected from a group comprising Cu and Al.
